(19) United States
(12) Patent Application Publication
(10) Pub. No.: US 2023/0207283 A1
(43) Pub. Date: Jun. 29, 2023

(54) PLASMA ETCHING SYSTEM AND FARADAY SHIELDING APPARATUS WHICH CAN BE USED FOR HEATING

(71) Applicant: BEIJING LEUVEN SEMICONDUCTOR TECHNOLOGY CO. LTD, Beijing (CN)

(72) Inventors: Song GUO, Beijing (CN); Haiyang LIU, Beijing (CN); Chengyi WANG, Beijing (CN); Shiran CHENG, Beijing (CN); Xiaobo LIU, Beijing (CN); Jun ZHANG, Beijing (CN); Dongdong HU, Beijing (CN); Kaidong XU, Beijing (CN)

(21) Appl. No.: 17/927,876

(22) PCT Filed: May 27, 2021
(86) PCT No.: PCT/CN2021/096196

§ 371 Date: Nov. 26, 2022

(30) Foreign Application Priority Data
May 28, 2020 (CN) 202020935350.8

(51) Int. Cl. H01J 37/32; H05B 1/02

(52) U.S. Cl. CPC H01J 37/32651; H01J 37/32119; H01J 37/32522; H05B 1/0233; H01J 2237/3341

(57) ABSTRACT

A Faraday shielding apparatus includes a Faraday shielding plate and a resistance wire attached to the lower end of the Faraday shielding plate; the Faraday shielding plate includes a conductive ring and a plurality of conductive petal-shaped members radially symmetrically connected to the outer periphery of the conductive ring; and an insulating and thermally conductivity layer is on the outer surface of the resistance wire. During the etching process, the heating circuit and the resistance wire are conductively connected, increasing the temperature of the resistance wire when it is energized. The Faraday shielding plate is between a radio frequency coil and the resistance wire to form a shield. The output terminal of the heating power supply is filtered by way of a filter circuit unit, then is connected to the resistance wire, preventing coupling between the radio frequency coil and the resistance wire.

### CROSS-REFERENCE TO RELATED APPLICATION

This application claims priority to Chinese patent application NO. 202020935350.8 filed on May 28, 2020 and entitled “PLASMA ETCHING SYSTEM AND FARADAY SHIELDING APPARATUS WHICH CAN BE USED FOR HEATING”, the disclosure of which is hereby incorporated by reference in its entirety.

### TECHNICAL FIELD

The present disclosure relates to the field of semiconductor etching, and in particular to a plasma etching system and a Faraday shielding apparatus which can be used for heating.

### BACKGROUND

In an etching process, voltages between different parts of a plasma coil is capacitively coupled to the plasma. Although this coupling promotes ignition and stability, the part of capacitive coupling is capable of causing a local enhanced voltage in the reaction chamber, which may accelerate ions leaving from the plasma to affect a dielectric window locally, resulting in local sputtering damages. In other situations, capacitive couplings may lead to local depositions. Sputtering may cause damages to the surface coatings on the dielectric window, and then the particles may fall off and may fall on the produced wafers, causing defects.

To solve the above problems, a technology for heating a dielectric window in a plasma etcher as illustrated in FIG. 1 is adopted in the prior art. As illustrated in FIG. 1, the main components are radio-frequency coils 001, a dielectric window 002, a heating net 004, a heat supplying fan 005, and an external shielding cover 006. The plasma generated by the radio-frequency coils 001 passes through the dielectric window 002 for processing, and heat generated by the heating net 004 is blown to the dielectric window 002 through the heat supplying fan 005 in the direction indicated by the arrow in a schematic diagram for heating. The main disadvantages of this method are the heat delivered by a fan is scattered, and the heating efficiency is low; on the other hand, the coils and other electrical components such as a matcher are heated at the same time, resulting in a high temperature and easy damages of electrical components; in order to prevent the heat wind from dispersing and the temperature from getting higher and higher, which will cause high temperature damages to the operator, the external shielding cover 006 is further needed, resulting in a complex structure, which will not only occupy additional space but also increase the cost.

In addition, although the heating of a ceramic dielectric window is capable of reducing the deposition amount of products, some products still deposit on the ceramic dielectric window, and after a period of time, the deposition increases to a certain amount, which still has an adverse effect on the etching process. In this case, it is still necessary to disassemble the chamber and further disassemble the ceramic dielectric window for manual cleaning

### SUMMARY

In order to solve the above technical problems, the exemplary embodiments of the present disclosure provide a plasma etching system and a Faraday shielding apparatus which can be used for heating thereof, in which by energizing the resistance wire in direct contact with the dielectric window to increase the temperature, the dielectric window is heated, the deposition amount of products is reduced, and the equipment structure is simplified with a high heating efficiency and a less heat loss.

Technical solutions are that: the present disclosure provides a Faraday shielding apparatus which can be used for heating of a plasma etching system. The apparatus comprises a Faraday shielding plate, the Faraday shielding plate includes a conductive ring and a plurality of conductive petal-shaped members radially and symmetrically connected to the outer periphery of the conductive ring, wherein the Faraday shielding apparatus further comprises a resistance wire attached to the lower end surface of the Faraday shielding plate, and the outer surface of the resistance wire is provided with an insulating and thermally conductive layer, and the resistance wire is energized and heated during an etching process.

Further, the Faraday shielding apparatus further comprises a heating circuit configured to supply power to the resistance wire; the heating circuit includes a heating power supply and a filter circuit unit; the output terminal of the heating power supply is connected to the resistance wire after being filtered by the filter circuit unit.

Further, the Faraday shielding apparatus further comprises a feedback control circuit; the feedback control circuit includes a temperature measurement sensor, a temperature controller and a solid state relay, and the solid state relay is arranged on the heating circuit and configured to control the heating circuit to be turned-on and turned-off; the temperature measurement sensor is configured to measure the temperature of the resistance wire and transmit data to the temperature controller; and the temperature controller controls the turn-on and turn-off of the solid state relay according to the set temperature and feedback signals.

Further, the pattern formed by wiring the resistance wire on the Faraday shielding plate is an open curve.

Further, the Faraday shielding plate is divided into a plurality of heating regions; each of the heating regions includes a section of the conductive ring and a plurality of conductive petal-shaped members connected to the section of the conductive ring, respectively; a resistance wire is arranged on each heating region; the resistance wire is wired along the conductive ring in the heating region and each conductive petal-shaped member in the heating region.

Further, the resistance wire is wired along a bow-shaped path on the lower end surface of the conductive petal-shaped member.

Further, the lower end surface of the Faraday shielding plate is provided with a wiring slot; the resistance wire is embedded in the wiring slot.

Provided is a plasma etching system including the above Faraday shielding apparatus which can be used for heating.

Further, the plasma etching system further includes a dielectric window, the Faraday shielding plate is integrally sintered in the dielectric window.

The beneficial effects of the present disclosure are that: in the present disclosure, during the etching process, the heating circuit and the resistance wire are conductively connected, so that the resistance wire and the Faraday shielding plate are energized to increase the temperature, heating the dielectric window, and reducing the deposition amount of products; the outer surface of the resistance wire is provided with an insulating and thermally conductivity layer, so that the resistance wire is insulated from the Faraday shielding plate and the Faraday shielding plate can be taken as a heat sink, thereby accelerating the heat diffusion of the resistance wire, improving the heating efficiency of the dielectric window, reducing the heat loss, and simplifying the equipment structure.

During the cleaning process, the heating circuit and the Faraday shielding plate are closed, the Faraday shielding plate is applied with the shielding power supply, and then the dielectric window is cleaned.

The Faraday shielding plate is located between the radio-frequency coils and the resistance wire to form a shield, on the one hand, it can effectively prevent the couplings between the radio-frequency coils and the resistance wire, affecting the radio frequency of the radio-frequency coil and the heating of the resistance wire; on the other hand, it can further prevent the resistance wire and the radio-frequency coils from discharging and burning the resistance wire.

The output terminal of the heating power supply is connected to the Faraday shielding plate after being filtered by the filter circuit unit, thereby effectively preventing the couplings between the radio-frequency coils and the Faraday shielding plate, which interfers with the radio frequency of the coils and the heating current of the Faraday shielding plate.

### BRIEF DESCRIPTION OF THE DRAWINGS

FIG. 1 illustrates a schematic diagram of a structure for heating a dielectric window in a plasma etcher in the prior art.

FIG. 2 illustrates a schematic diagram of the present disclosure.

FIG. 3 illustrates a top view of a Faraday shielding plate of the present disclosure.

FIG. 4 illustrates a partial enlarged view of the Faraday shielding plate of the present disclosure.

FIG. 5 illustrates a partial enlarged view of a connection point between the Faraday shielding plate and the dielectric window of the present disclosure.

FIG. 6 illustrates a process flow chart of applying the present disclosure.

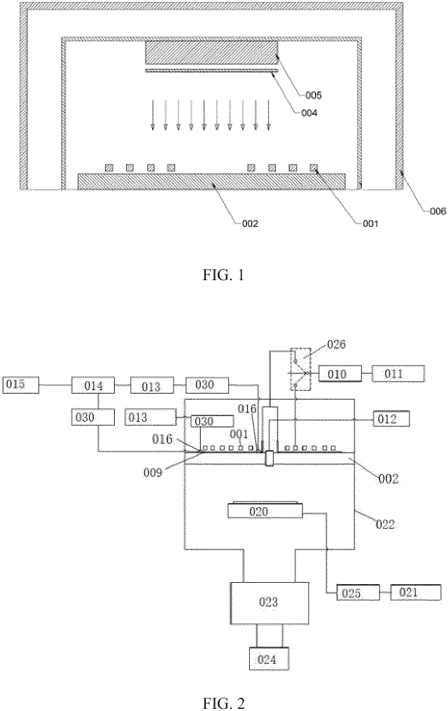

### DETAILED DESCRIPTION OF THE EMBODIMENTS

As illustrated in FIG. 2, the exemplary embodiments in the present disclosure provides a plasma etching system. The system includes a reaction chamber 022, radio-frequency coils 001 and a bias electrode 020.

A dielectric window 002 is arranged above the reaction chamber 022, and the radio-frequency coils 001 are located above the dielectric window 002. The radio-frequency coils 001 are powered by the excitation radio-frequency power supply 011 after being tuned by the excitation matching network 010.

The bias electrode 020 is located in the reaction chamber 022, and is powered by the bias radio-frequency power supply 021 after being tuned by the bias matching network 025.

A vacuum pump 024 and a pressure control valve 023 are further arranged at the lower end of the reaction chamber 022, which are configured to maintain a vacuum degree required by the reaction chamber 022.

The plasma etching system further includes a gas source 012 configured to provide process gas to the reaction chamber 022 and the process gas enters the reaction chamber 022 through the dielectric window 002.

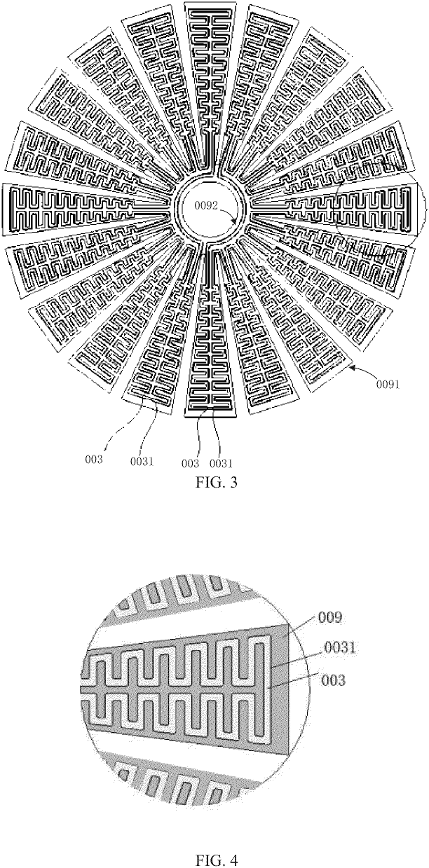

As illustrated in FIG. 3, the plasma etching system further comprises a Faraday shielding apparatus which can be used for heating. The Faraday shielding apparatus includes a Faraday shielding plate 009. The Faraday shielding plate 009 includes a conducting ring 0092 and a plurality of conductive petal-shaped members 0091 radially and symmetrically connected to the outer periphery of the conductive ring 0092. In this embodiment, the Faraday shielding plate 009 is further powered through the excitation radio-frequency power supply 011 after being tuned by the excitation matching network 010, and the excitation radio-frequency power supply 011 is adopted as a shielding power supply. The output terminal of the excitation matching network 010 is capable of being connected to the radio-frequency coils 001 or the Faraday shielding plate 009 through a three-phase switch 026.

During the etching process, a wafer is placed on the bias electrode 020. The reaction gas in the plasma treatment process, such as fluorine, is introduced into the reaction chamber 022 through the gas source 012. A specific pressure in the reaction chamber 022 is maintained by the pressure control valve 023 and the vacuum pump 024. The excitation radio-frequency power supply 011 is tuned through the excitation matching network 010, and supplies power to the radio-frequency coils 001 through the three-phase switch 026. Plasma is generated in reaction chamber 022 through inductive couplings, and the wafer is treated by the plasma treatment process. When the plasma treatment process is completed, an input of radio-frequency power is stopped and an input of the reaction gas in the plasma treatment process is stopped.

When the cleaning process is required, the substrate is placed on the bias electrode 020. The reaction gas in the cleaning process, such as argon, oxygen and nitrogen trifluoride, is introduced into the reaction chamber 022 through the gas source 012. The specific pressure of the reaction chamber 022 is maintained through the pressure control valve 023 and the vacuum pump 024. The excitation radio-frequency power supply 011 is tuned by the excitation matching network 010, and supplies the power to the Faraday shield Panel 009 via the three-phase switch 026. The power from the Faraday shielding plate 009 generates argon ions, and the like, which are sputtered to the inner wall of the dielectric window 002 to clean the dielectric window 002. When the cleaning process is completed, the input of the radio-frequency power is stopped and an input of the reaction gas in the cleaning process is stopped.

The Faraday shielding apparatus further comprises a resistance wire 003 attached to the lower end surface of the Faraday shielding plate and a heating circuit. In this embodiment, the lower end surface of the Faraday shielding plate is provided with a wiring slot; the resistance wire 003 is embedded in the wiring slot, which can save space. The heating circuit includes a heating power supply 015, and when the heating power supply 015 is used for the etching process, the resistance wire 003 is energized and heated. The outer surface of the resistance wire 003 is provided with an insulating and thermally conductivity layer 0031, so that the resistance wire 003 is insulated from the Faraday shielding plate 009 and the Faraday shielding plate 009 can be taken as a heat fin, thereby accelerating the heat diffusion of resistance wire 003 and improving the heating efficiency of the dielectric window 002.

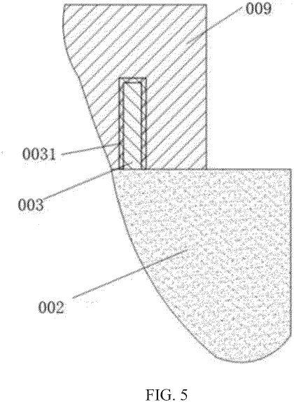

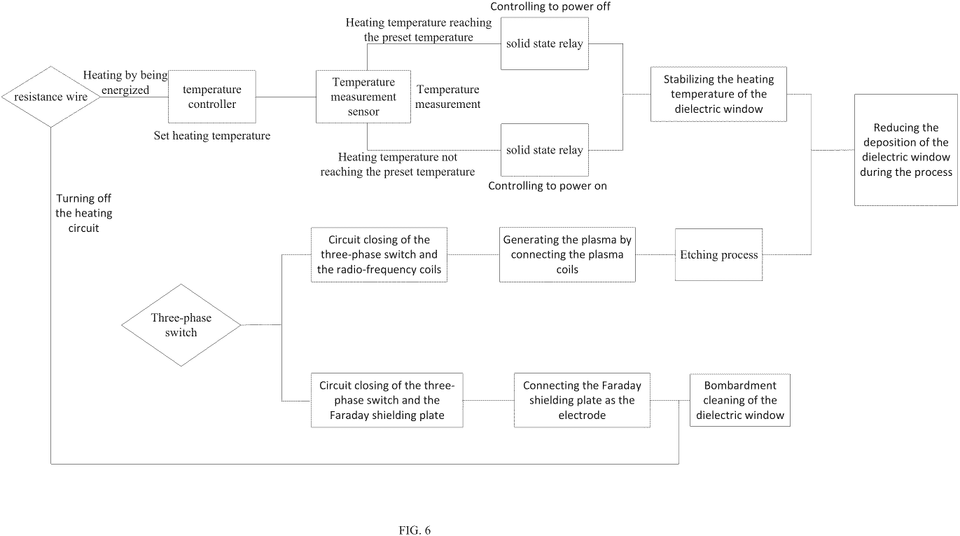

As illustrated in FIG. 4, an application method is specifically as follows. During the etching process, the etching reaction gas is introduced into the reaction chamber 022, and the excitation radio-frequency power supply 011 is applied to the radio-frequency coils 001, and plasma is generated to etch the substrate sheet. At the same time, the heating circuit is conductively connected to the resistance wire 003, increasing the temperatures of the resistance wire 003 and the Faraday shielding plate 009 when they are energized, heating the dielectric window 002, and reducing the deposition amount of products. In this embodiment, the Faraday shielding plate 009 is integrally sintered in dielectric window 002 to improve the heating efficiency.

During the cleaning process, the heating circuit and the resistance wire 003 are turned off. The cleaning reaction gas is introduced into the reaction chamber 022, and the Faraday shielding plate 009 is applied with the shielding power supply to clean the dielectric window 002.

During the etching process, the excitation radio-frequency power supply 011 is tuned by the excitation matching network 010, and supplies the power to the radio-frequency coils 001 through the three-phase switch 026. The Faraday shielding plate 009 is located between the radio-frequency coils 001 and the resistance wire 003 to form a shield, on the one hand, it can effectively prevent the couplings between radio-frequency coils 001 and resistance wire 003, affecting the radio-frequency of the radio-frequency coils 001 and the heating of the resistance wire 003; on the other hand, it can further prevent the resistance wire 003 and the radio-frequency coils 001 from discharging and burning the resistance wire 003.

The heating circuit of the present disclosure further includes a filter circuit unit 030. The output terminal of the heating power supply 015 is connected to the Faraday shielding plate 009 after being filtered by the filter circuit unit 030 to effectively prevent the couplings between the radio-frequency coils 001 and the Faraday shielding plate 009.

The plasma etching system further includes a feedback control circuit; the feedback control circuit includes a temperature measurement sensor 016, a temperature controller 013 and a solid state relay 014; the solid state relay 014 is arranged on the heating circuit and configured to control the heating circuit to be tumed-on and turned-off. The temperature measurement sensor 016 is configured to measure the temperature of the resistance wire 003 and transmit data to the temperature controller 013; and the temperature controller 013 controls the turn-on and turn-off of the solid state relay 014 according to the set temperature and feed back signals. When the resistance wire 003 reaches the high temperature set by temperature controller 013, the resistance wire 003 feeds back the signals to control the circuit to be turned off through the solid state relay 014; when the temperature of the resistance wire 003 drops below the set low temperature, the temperature measurement sensor 016 detects the temperature drop and then transmits data to temperature controller 013. The resistance wire 003 feeds back the signals again to control the circuit to be turned on for heating through the solid state relay 014, thus the feedback control circuit enables the resistance wire 003 to maintain an appropriate temperature. For the sake of insurance, two sets of the temperature measurement sensors 016 and the temperature controllers 013 can be set to control the solid state relay 014 in parallel, which is capable of preventing control failures and equipment damages due to damages of the temperature measurement sensor 016 or the temperature controller 013. Two sets of the temperature measurement sensors 016 are capable of measuring different positions of the resistance wire 003 to prevent the temperature of the resistance wire 003 from being unbalanced and prevent the local temperature of the resistance wire 003 from being too high or too low.

In order to prevent the couplings between the feedback control circuit and the radio-frequency coils 001 during the etching process, the filter circuit unit 030 is further arranged on the feedback control circuit.

When the resistance wire 003 is wired on the lower end surface of the Faraday shielding plate 009 to form a closed ring, the radio-frequency of the RF coil 001 will be shielded. Therefore, the pattern formed by wiring the resistance wire 003 on the Faraday shielding plate 009 is an open curve.

The preferred wiring mode is as follows: the Faraday shielding plate 009 is divided into a plurality of heating regions; each of the heating regions includes a section of the conductive ring 0092 and a plurality of conductive petal-shaped members 0091 connected to the section of the conductive ring 0092, respectively; a resistance wire 003 is arranged on each heating region; the resistance wire 003 is wired along the conductive ring 0092 in the heating region and each conductive petal-shaped member 0091 in the heating region. In this embodiment, the Faraday shielding plate is divided into two heating regions.

In order to enable the heating more uniform, the resistance wire 003 is wired along the bow-shaped path on the lower end surface of the conductive petal-shaped member 0091.

1. A Faraday shielding apparatus which can be used for heating in a plasma etching system, comprising a Faraday shielding plate, the Faraday shielding plate includes a conductive ring and a plurality of conductive petal-shaped members radially and symmetrically connected to an outer periphery of the conductive ring, wherein the Faraday shielding apparatus further comprises a resistance wire attached to a lower end surface of the Faraday shielding plate, and an outer surface of the resistance wire is provided with an insulating and thermally conductive layer, and the resistance wire is energized and heated during an etching process.

2. The Faraday shielding apparatus according to claim 1, wherein the Faraday shielding apparatus further comprises a heating circuit configured to supply power to the resistance wire; the heating circuit includes a heating power supply and a filter circuit unit; an output terminal of the heating power supply is connected to the resistance wire after being filtered by the filter circuit unit.

3. The Faraday shielding apparatus according to claim 2, wherein the Faraday shielding apparatus further comprises a feedback control circuit; the feedback control circuit includes a temperature measurement sensor, a temperature controller and a solid state relay, and the solid state relay is arranged on the heating circuit and configured to control the heating circuit to be turned-on and turned-off; the temperature measurement sensor is configured to measure a temperature of the resistance wire and transmit data to the temperature controller; and the temperature controller controls a turn-on and turn-off of the solid state relay according to a set temperature and feedback signals.

4. The Faraday shielding apparatus according to claim 1, wherein a pattern formed by wiring the resistance wire on the Faraday shielding plate is an open curve.

5. The Faraday shielding apparatus according to claim 4, wherein the Faraday shielding plate is divided into a plurality of heating regions; each of the heating regions includes a section of the conductive ring and a plurality of conductive petal-shaped members connected to the section of the conductive ring, respectively; a resistance wire is arranged on each heating region; the resistance wire is wired along the conductive ring in the heating region and each conductive petal-shaped member in the heating region.

6. The Faraday shielding apparatus according to claim 5, wherein the resistance wire is wired along a bow-shaped path on the lower end surface of the conductive petal-shaped member.

7. The Faraday shielding apparatus according to claim 1, wherein the lower end surface of the Faraday shielding plate is provided with a wiring slot; the resistance wire is embedded in the wiring slot.

8. A plasma etching system, wherein the plasma etching system comprises a Faraday shielding apparatus which can be used for heating according to claim 1.

9. The plasma etching system according to claim 8, wherein the plasma etching system further includes a dielectric window, the Faraday shielding plate is integrally sintered in the dielectric window.
